(19) United States
(12) Patent Application Publication
(10) Pub. No.: US 2025/0098308 A1
(43) Pub. Date: Mar. 20, 2025

(54) Chip on Glass Type Driver Chip and Display Apparatus Including the Same

(71) Applicant: LG Display Co., Ltd., Seoul (KR)

(72) Inventor: Yeon Wook Kang, Paju-si (KR)

(21) Appl. No.: 18/763,960

(22) Filed: Jul. 3, 2024

(30) Foreign Application Priority Data
Sep. 18, 2023 (KR) 10-2023-0124045

(51) Int. Cl. H01L 27/12; G09G 3/20

(52) U.S. Cl. CPC H10D 86/60; G09G 3/2092; H10D 86/441; G09G 2310/0267; G09G 2310/0275

(57) ABSTRACT

A chip on glass (COG) type driver chip includes a base substrate, at least one insulation layer and at least one line layer alternately stacked on the base substrate, and a bump array disposed on an uppermost layer of the base substrate, wherein the bump array includes a plurality of input bumps passing through the at least one insulation layer and connected to metal lines of the at least one line layer, a plurality of output bumps passing through the at least one insulation layer and connected to the metal lines of the at least one line layer, and a plurality of dummy bumps electrically disconnected from the at least one line layer with the at least one insulation layer therebetween.

### CROSS-REFERENCE TO RELATED APPLICATIONS

This application claims the benefit of the Korean Patent Application No. 10-2023-0124045 filed on Sep. 18, 2023, which is hereby incorporated by reference as if fully set forth herein.

### BACKGROUND

### Field of the Invention

The present disclosure relates to a chip on glass (COG) type driver chip and a display apparatus including the same.

### Discussion of the Related Art

Display apparatuses include a display panel where a plurality of pixels are provided and a driver integrated circuit (IC) which supplies a driving signal to the pixels.

The driver IC may be implemented as a chip on glass (COG) type driver chip which is mounted on a substrate of the display panel through a COG process. The COG process is a process which applies heat and pressure to a driver chip for a certain time by using an anisotropic conductive film (ACF), and thus, bonds the driver chip to the display panel. A resin of the ACF is dissolved by heat and pressure, and a conductive ball in the resin is compressed between the driver chip and the substrate, whereby a bump of the driver chip is electrically connected to a signal pad of the display panel. Such a COG process may implement a driver chip where an electrical characteristic is relatively good and a mount area and a thickness are reduced, compared to a chip on film (COF) process.

COG type driver chips may have a problem of warpage which occurs due to a coefficient difference of thermal expansion between different materials having different physical properties. When a warpage level is large, the bonding quality of a COG process may be degraded. Also, a micro crack may occur in a driver chip due to a stress applied from the outside for a COG bonding process.

### SUMMARY

To overcome the aforementioned problem of the related art, the present disclosure may provide a chip on glass (COG) type driver chip and a display apparatus including the same, in which a warpage level is reduced.

Moreover, the present embodiment may provide a chip on glass (COG) type driver chip and a display apparatus including the same, which is reduced in warpage level and is robust to a micro crack.

To achieve these objects and other advantages and in accordance with the purpose of the disclosure, as embodied and broadly described herein, a chip on glass (COG) type driver chip includes a base substrate, at least one insulation layer and at least one line layer alternately stacked on the base substrate, and a bump array disposed on an uppermost layer of the base substrate, wherein the bump array includes a plurality of input bumps passing through the at least one insulation layer and connected to metal lines of the at least one line layer, a plurality of output bumps passing through the at least one insulation layer and connected to the metal lines of the at least one line layer, and a plurality of dummy bumps electrically disconnected from the at least one line layer with the at least one insulation layer therebetween.

In another aspect of the present disclosure, a display apparatus includes a display panel including a display area where pixels are provided and a bezel region outside the display area and the COG type driver chip mounted directly on a substrate of the display panel disposed in the bezel region.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a block diagram illustrating a display apparatus according to the present embodiment;

FIGS. 2 and 3 are diagrams illustrating a source driver integrated circuit (IC) implemented with chip on glass (COG) type driver chips;

FIG. 4 is a diagram illustrating a bump configuration installed at a surface of one driver chip according to the present embodiment;

FIG. 5 is a diagram illustrating an internal stack configuration of one driver chip according to the present embodiment;

FIG. 6 is a diagram illustrating a connection structure between an input bump and a metal line in one driver chip according to the present embodiment;

FIG. 7 is a diagram illustrating a connection structure between an output bump and a metal line in one driver chip according to the present embodiment;

FIG. 8 is a diagram illustrating a floating structure of a dummy bump corresponding to a metal line in one driver chip according to the present embodiment;

FIG. 9 is a diagram illustrating an example of a line layer included in one driver chip according to the present embodiment;

FIG. 10 is a diagram illustrating a cross-sectional surface taken along line A-A′ of FIG. 9; and

FIGS. 11 to 13 are diagrams illustrating another example of a line layer included in one driver chip according to the present embodiment.

### DETAILED DESCRIPTION OF THE DISCLOSURE

Hereinafter, the present disclosure will be described more fully with reference to the accompanying drawings, in which exemplary embodiments of the disclosure are shown. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Furthermore, the present disclosure is only defined by scopes of claims.

The shapes, sizes, ratios, angles, numbers and the like disclosed in the drawings for description of various embodiments of the present disclosure to describe embodiments of the present disclosure are merely exemplary and the present disclosure is not limited thereto. Like reference numerals refer to like elements throughout. Throughout this specification, the same elements are denoted by the same reference numerals. As used herein, the terms “comprise”, “having,” “including” and the like suggest that other parts can be added unless the term “only” is used. As used herein, the singular forms “a”, “an”, and “the” are intended to include the plural forms as well, unless context clearly indicates otherwise.

Elements in various embodiments of the present disclosure are to be interpreted as including margins of error even without explicit statements.

In describing a position relationship, for example, when a position relation between two parts is described as “on˜”, “over˜”, “under˜”, and “next˜”, one or more other parts may be disposed between the two parts unless “just” or “direct” is used.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

In the following description, when the detailed description of the relevant known function or configuration is determined to unnecessarily obscure the important point of the present disclosure, the detailed description will be omitted. Hereinafter, embodiments of the present disclosure will be described in detail with reference to the accompanying drawings.

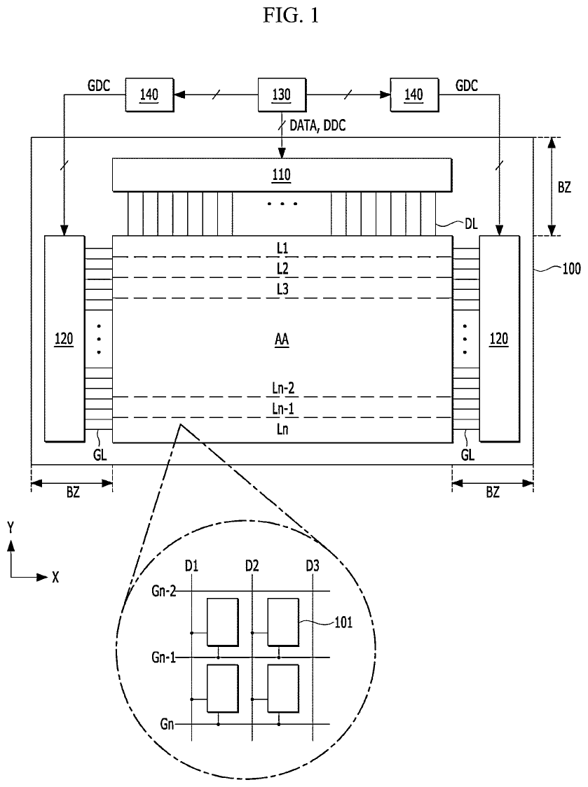

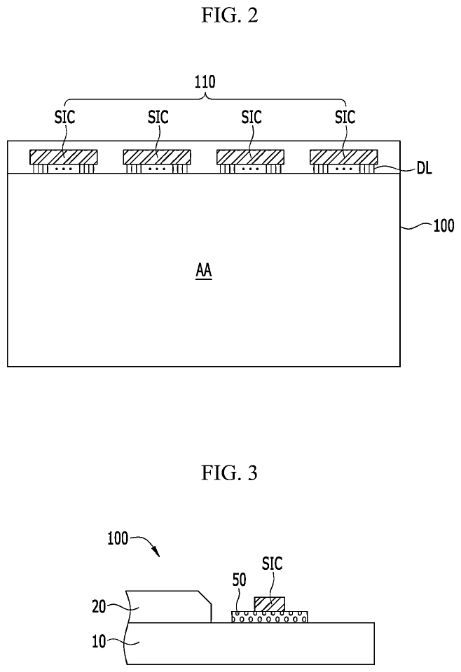

FIG. 1 is a block diagram illustrating a display apparatus according to the present embodiment. FIGS. 2 and 3 are diagrams illustrating a source driver integrated circuit (IC) implemented with chip on glass (COG) type driver chips.

Referring to FIGS. 1 to 3, the display apparatus according to the present embodiment may be implemented as a flat display apparatus such as a liquid crystal display (LCD) apparatus, an electroluminescent display apparatus, an electrophoretic display apparatus, an electro-wetting display apparatus, an organic light emitting display apparatus, or a quantum dot display apparatus. Furthermore, the display apparatus according to the present embodiment is not limited to the flat display apparatus and may be implemented as various types such as a curved display apparatus, a foldable display apparatus, a rollable display apparatus, and a transparent display apparatus.

In the following embodiments, the display apparatus may be described as a flat LCD apparatus, but the inventive concept is not limited thereto.

The display panel 100 may include two glass substrates 10 and 20 and a liquid crystal layer formed therebetween. A plurality of data lines DL, a plurality of gate lines GL intersecting with the data lines DL, and a pixel electrode may be formed on a lower glass substrate 20 of the display panel 100.

A black matrix, a color filter, and a common electrode may be formed on an upper glass substrate 10 of the display panel 100. The common electrode may be formed on an upper glass substrate 10 of the display panel 100. The common electrode may be formed on the upper glass substrate 10 in a vertical electric field mode such as a twisted nematic (TN) mode or a vertical alignment (VA) mode and may be formed on the upper glass substrate 10 along with the pixel electrode in a lateral electric field mode such as an in plane switching (IPS) mode or a fringe field switching (FFS) mode.

Liquid crystal cells may be arranged as a matrix type in the display panel 100, based on an intersection structure between the data lines DL and the gate lines GL. Each of the liquid crystal cells may include a thin film transistor (TFT), a pixel electrode connected to the TFT, and a storage capacitor.

In the display panel 100, the liquid crystal cells may configure a screen AA where an input image is reproduced. The screen AA may include a pixel array which displays pixel data of the input image (hereinafter referred to as image data) DATA. The pixel array may include the plurality of data lines DL, the plurality of gate lines GL intersecting with the data lines DL, and a plurality of pixels. The pixels may be arranged as various types, such as a matrix type, a stripe type, or a diamond type, on the screen AA. Each of the pixels may include a red (R) liquid crystal cell 101, a green (G) liquid crystal cell 101, and a blue (B) liquid crystal cell 101 so as to implement colors.

A polarizer may be attached on each of the upper glass substrate 10 and the lower glass substrate 20 of the display panel 100, and an alignment layer for setting a pre-tilt angle of the liquid crystal layer may be formed at on an inner surface contacting the liquid crystal layer.

The pixel array may include a plurality of pixel columns and a plurality of pixel lines L1 to Ln intersecting with the pixel columns. Each of the pixel columns may include pixels which are arranged in a Y-axis direction. A pixel line may include pixels which are arranged in an X-axis direction. One vertical period may be one frame period needed for writing image data DATA of one frame in all pixels of the screen. One horizontal period may be a time obtained by dividing one frame period by the number of pixel lines L1 to Ln. One horizontal period may be a time needed for writing the image data DATA of one pixel line, sharing a gate line GL, in pixels of one pixel line. In FIG. 1, “D1 to D3” illustrated in a circle may be data lines, and “Gn-2 to Gn” may be gate lines.

A display panel driver may include a source driver 110 and a gate driver 120. The display panel driver may write image data DATA in the pixels of the display panel 100, based on control by the timing controller 130.

The source driver 110 may include a digital-to-analog converter (DAC). The DAC may receive the image data DATA and a source timing control signal DDC from the timing controller 130. The DAC may convert the image data DATA into a gamma compensation voltage to generate data voltages, based on the source timing control signal DDC, and may supply the data voltages to the data lines DL during one horizontal period. The data voltages may be supplied to the data lines DL and may then be applied to the pixel electrodes of the liquid crystal cells 101 through TFTs.

The source driver 110 may be disposed outside the screen AA in the display panel 100 and may be formed in a first bezel region BZ (i.e., a Y-axis bezel region) which does not display an image. The source driver 110 may include a plurality of source driver chips SIC. Each of the plurality of source driver chips SIC may be implemented as a chip on glass (COG) type source driver chip SIC mounted directly on the lower glass substrate 20 of the display panel 100 through a COG process. Based on a COG process using an anisotropic conductive film (ACF), a first output bump of the source driver chip SIC may be bonded to a data input pad of the lower glass substrate 20 (here, may be connected to the data lines DL). A resin of the ACF 50 may be dissolved by heat and pressure, and a conductive ball in the resin of the ACF 50 may be compressed between the source driver chip SIC and the lower glass substrate 20, whereby a first output bump of the source driver chip SIC may be electrically connected to a data input pad of the display panel 100. Such a COG type source driver chip SIC may have a good electrical characteristic and may be small in mount area and thickness, compared to a case which is implemented as a chip on film (COF) type.

The COG type source driver chip SIC may include the first output bump, a first output pad connected to the first output bump, a first input bump connected to the timing controller 130 through an internal interface circuit, and a first input pad electrically connecting the first input bump to the DAC.

The gate driver 120 may sequentially supply a gate signal, synchronized with a data voltage, to the gate lines GL according to control by the timing controller 130. The gate signal may simultaneously activate pixels of a pixel line charged with the data voltage during at least one horizontal period. The gate driver 120 may include one or more gate shift registers. The gate shift register may output the gate signal while shifting the gate signal in a line progressive/non-progressive scheme, based on a gate timing control signal GDC. The gate signal may include one or more scan signals.

The gate driver 120 may be disposed outside the screen AA in the display panel 100 and may be formed in a second bezel region BZ (i.e., an X-axis bezel region) which does not display an image. The gate driver 120 may include a plurality of gate driver chips. Each of the plurality of gate driver chips may be implemented as a COG type gate driver chip mounted directly on the lower glass substrate 20 of the display panel 100 through a COG process. Based on a COG process using an ACF, a second output bump of the gate driver chip may be bonded to a gate input pad of the lower glass substrate 20 (here, may be connected to the gate lines GL). The resin of the ACF 50 may be dissolved by heat and pressure, and a conductive ball in the resin of the ACF 50 may be compressed between the gate driver chip and the lower glass substrate 20, whereby a second output bump of the gate driver chip may be electrically connected to a gate input pad of the display panel 100.

The COG type gate driver chip may include the second output bump, a second output pad connected to the second output bump, a second input bump connected to a level shifter 140 through a line on glass (LOG) line, and a second input pad electrically connecting the second input bump to the gate shift register.

The timing controller 130 may receive video data DATA and a timing signal, synchronized with the video data DATA, from a host system. The timing signal may include a vertical synchronization signal Vsync, a horizontal synchronization signal Hsync, a clock signal DCLK, and a data enable signal DE. The vertical synchronization signal Vsync may define a vertical period (i.e., one frame). The horizontal synchronization signal Hsync may define a horizontal period. The data enable signal DE may define a time where the video data DATA is transferred in a vertical period or a horizontal period. The vertical period and the horizontal period may be detected by a method of counting the data enable signal DE, and thus, the vertical synchronization signal Vsync and the horizontal synchronization signal Hsync may be omitted.

The timing controller 130 may generate the source timing control signal DDC for controlling an operation timing of the source driver 110 and the gate timing control signal GDC for controlling an operation timing of the gate driver 120, based on the timing signals Vsync, Hsync, and DE received from the host system. The source timing control signal DDC may include a source sampling clock for sampling image data DATA and a source output enable signal for setting an output timing of a data voltage.

The timing controller 130 may multiply an input frame frequency by i (where i may be a natural number) times to control an operation timing of each of the source driver 110 and gate driver 120 of the display panel, based on a frame frequency of an input frame frequency X i Hz. The input frame frequency may be about 60 Hz in national television standards committee (NTSC) scheme and may be about 50 Hz in phase-alternating line (PAL) scheme.

The host system be one of a television (TV), a set-top box, a navigation system, a personal computer (PC), a home theater, an automotive display system, a mobile device, and a wearable device. In the mobile device and the wearable device, the source driver 110, the timing controller 130, and the level shifter 140 may be integrated into one driver integrated circuit (IC).

The level shifter 140 may shift a logic voltage of the gate timing control signal GDC having a first amplitude, input from the timing controller 130, to a gate high voltage VGH or a gate low voltage VGL, having a second amplitude which is greater than the first amplitude, to supply to the gate driver 120. Based on the level shifter, a low logic voltage of the gate timing control signal GDC may be shifted to the gate low voltage VGL, and a high logic voltage of the gate timing control signal GDC may be shifted to the gate high voltage VGH.

The timing controller 130 may transfer the image data DATA and the source timing control signal DDC to the source driver chips SIC through the internal interface circuit. The internal interface circuit may be implemented as an embedded clock point to point interface (EPI), but is not limited thereto.

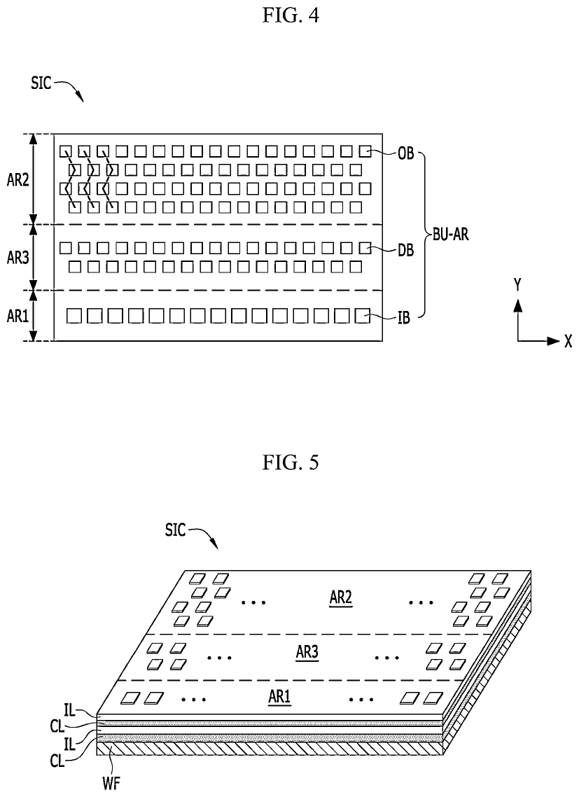

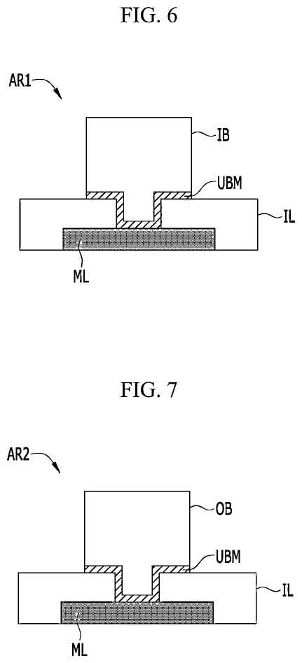

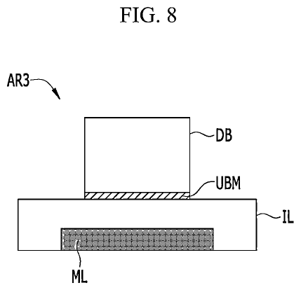

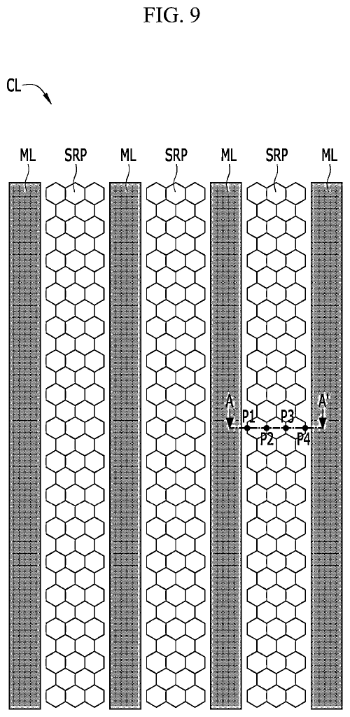

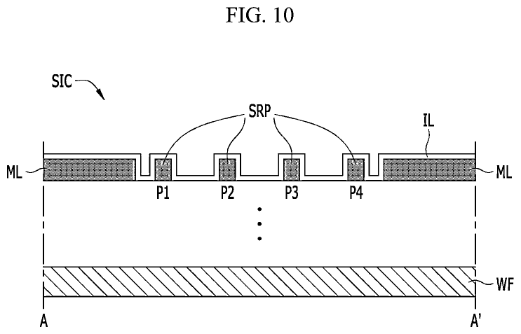

FIG. 4 is a diagram illustrating a bump configuration installed at a surface of one driver chip according to the present embodiment. FIG. 5 is a diagram illustrating an internal stack configuration of one driver chip according to the present embodiment. FIG. 6 is a diagram illustrating a connection structure between an input bump and a metal line in one driver chip according to the present embodiment. FIG. 7 is a diagram illustrating a connection structure between an output bump and a metal line in one driver chip according to the present embodiment. FIG. 8 is a diagram illustrating a floating structure of a dummy bump corresponding to a metal line in one driver chip according to the present embodiment.

One driver chip of FIGS. 4 to 8 may be described as a source driver chip SIC, but the inventive concept is not limited to the source driver chip SIC and may be identically applied to a gate driver chip.

Referring to FIGS. 4 and 5, a source driver chip SIC according to the present embodiment may include a base substrate WF, one or more insulation layers IL and one or more line layers CL which are alternately stacked on the base substrate WF, and a bump array BU-AR which is disposed in an uppermost layer of the base substrate WF.

The base substrate WF may be a glass substrate or a plastic substrate, but is not limited thereto.

The bump array BU-AR may include a plurality of input bumps IB which pass through the insulation layer IL and are connected to metal lines (ML of FIG. 6) of the line layer CL, a plurality of output bumps OB which pass through the insulation layer IL and are connected to metal lines (ML of FIG. 7) of the line layer CL, and a plurality of dummy bumps DB which are electrically disconnected from the line layer CL with the insulation layer IL therebetween.

The COG type source driver chip SIC may have a problem of warpage which occurs due to a coefficient difference of thermal expansion between different materials having different physical properties. When a transverse length and a longitudinal length of the source driver chip SIC differ, the degree of warpage in a transverse direction (hereinafter referred to as an X-axis direction) and the degree of warpage in a longitudinal direction (hereinafter referred to as a Y-axis direction) may be changed. The degree of warpage may be proportional to a length of the source driver chip SIC and may be inversely proportional to a thickness thereof, and as the degree of warpage increases, COG bonding indentation may be affected thereby, causing a degradation in the bonding quality of a COG process.

Considering the fundamental purpose of a COG process, it may be difficult to apply an operation, which increases a thickness of the source driver chip SIC so as to reduce the degree of warpage, to the present disclosure. In the present embodiment, the bump array BU-AR may include dummy bumps DB, so as to reduce the degree of warpage without an increase in thickness of the source driver chip SIC.

The dummy bumps DB may be provided at a center portion, where the input bumps IB and the output bumps OB are not provided, of the bump array BU-AR so as to function as a supporter for decreasing the degree of warpage.

In detail, when the bump array BU-AR includes a first region AR1, a second region AR2 facing the first region AR1, and a third region AR3 disposed between the first and second regions AR1 and AR2, the input bumps IB may be disposed in the first region AR1, and the output bumps OB may be disposed in the second region AR2. In this case, the dummy bumps DB may be disposed in the third region AR3 corresponding to the center portion of the bump array BU-AR. In FIG. 4, it is illustrated that the bump array BU-AR is divided into the first to third regions AR1 to AR3 in the Y-axis direction, but the first to third regions AR1 to AR3 may be designed to be divided in the X-axis direction.

To more reinforce a function of a supporter for decreasing the degree of warpage, the dummy bumps DB may be arranged in a plurality of rows in the third region AR3 of the bump array BU-AR, and thus, may be provided at a high density in a predetermined mount area. Dummy bumps DB of a plurality of rows may disperse a compression stress which is relatively high in the third region AR3 in performing a COG bonding process.

Furthermore, the input bumps IB may be arranged in a single row in the first region AR1 of the bump array BU-AR, but is not limited thereto. As illustrated in FIGS. 4 and 5, the output bumps OB may be arranged in a plurality of rows having a zigzag shape the second region AR2 of the bump array BU-AR, and thus, may be provided at a high density in a predetermined mount area. Because the output bumps OB should be connected to data input pads of the display panel, the number of output bumps OB may be more than the number of input bumps IB.

To secure the easiness of design, at least one of the input, output, and dummy bumps IB, OB, and DB may have an individual plane size which is relatively large. For example, as illustrated in FIGS. 4 and 5, each input bump IB may have an individual plane size which is relatively greater than each output bump OB or each dummy bump DB. Each output bump OB or each dummy bump DB may have the same individual plane size, but is not limited thereto. Each output bump OB and each dummy bump DB may have different individual plane sizes.

Moreover, the first to third regions AR1 to AR3 configuring the bump array BU-AR may have different individual plane sizes. The second region AR2 where the output bumps OB are disposed may be relatively largest, the third region AR3 where the dummy bumps DB for preventing warpage are disposed may be second large, and the first region AR1 where the input bumps IB are disposed may be relatively smallest.

To more decrease the degree of warpage, the metal lines ML of the line layer CL may be disposed under the bump array BU-AR and may be disposed to correspond to an entire region of the bump array BU-AR. In other words, the metal lines ML of the line layer CL may be disposed under the first and second regions AR1 and AR2, and moreover, may be disposed under the third region AR3. The metal lines ML of the line layer CL may be electrically disconnected from each other.

Referring to FIG. 6, in the first region AR1, an under bump metallization (UBM) contacting lower surfaces of the input bumps IB may pass through the insulation layer IL and may be connected to the metal lines ML. Metal lines ML electrically connected to the input bumps IB may be input pads of the source driver chip SIC.

Referring to FIG. 7, in the second region AR2, a UBM contacting lower surfaces of the output bumps OB may pass through the insulation layer IL and may be connected to the metal lines ML. Metal lines ML electrically connected to the output bumps OB may be output pads of the source driver chip SIC. The output pads may be connected to data input pads of the display panel through the output bumps OB. The data input pads may extend from the data lines and may be included in the display panel.

Referring to FIG. 8, in the third region AR3, a UBM contacting lower surfaces of the dummy bumps DB may be electrically disconnected from the metal lines ML by the insulation layer IL. The dummy bumps DB may not be connected to any metal lines ML, may not be connected to any data input pads, and may be electrically floated. Because the dummy bumps DB are not needed to be connected to any metal lines ML, the degree of freedom in designing of the dummy bumps DB may increase.

Furthermore, in the source driver chip SIC, an uppermost line layer CL may be covered by an uppermost insulation layer IL, but due to a space between metal lines ML disposed in the uppermost line layer CL, a valley may occur in the uppermost insulation layer IL. Due to the valley, a compression stress and a tension stress may be applied to the uppermost insulation layer IL in performing a COG bonding process. Also, comparing with the input and output bumps IB and OB, a relatively high compression stress may be applied to the dummy bumps DB, and a relatively high tension stress may be applied to peripheries of the dummy bumps DB. A micro crack may occur in the COG type source driver chip SIC due to an influence of a complex stress.

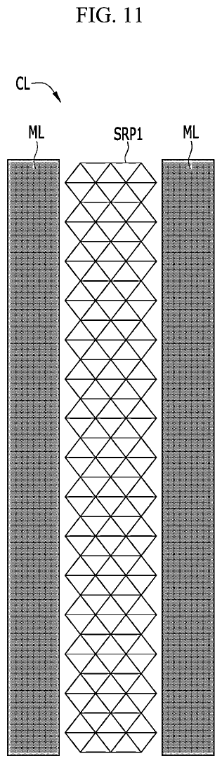

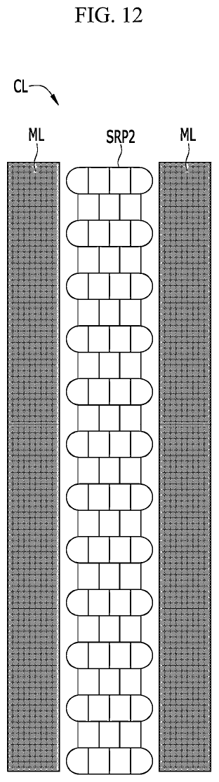

FIG. 9 is a diagram illustrating an example of a line layer included in one driver chip according to the present embodiment. FIG. 10 is a diagram illustrating a cross-sectional surface taken along line A-A′ of FIG. 9. In FIG. 10, the bump array described above is omitted.

Referring to FIGS. 9 and 10, a source driver chip SIC according to the present embodiment may be designed to decrease in degree of warpage and be robust to a micro crack. To this end, each of line layers CL included in the source driver chip SIC according to an embodiment may further include shock-resistant patterns SRP which are disposed in a region between adjacent metal lines ML. When a stress is applied to metal lines ML, the shock-resistant patterns SRP may absorb a shock caused by the stress. Because the shock-resistant patterns SRP are for shock absorption, the shock-resistant patterns SRP may be electrically insulated from the metal lines ML and may also be electrically insulated from input bumps IB, output bumps OB, and dummy bumps DB.

The shock-resistant patterns SRP may include a conductive material or a nonconductive material and may be implemented in a structure robust to an external stress. To this end, a plurality of insulation patterns having a hexagonal shape may be connected to each other, and thus, the shock-resistant patterns SRP may be designed in a honeycomb structure. A plurality of components P1, P2, P3 and P4 for forming the honeycomb structure of the shock-resistant patterns SRP are schematically marked and shown in FIGS. 9 and 10. The honeycomb structure may be a structure where a stress is uniformly and stably distributed. According to a tension experiment, graphene having a honeycomb shape may have strength which is about 200 times strength of steel and may have a good physical characteristic for shock absorption.

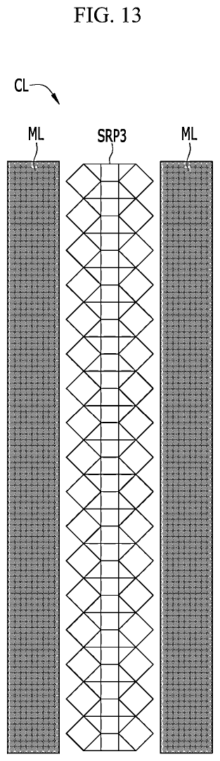

FIGS. 11 to 13 are diagrams illustrating another example of a line layer included in one driver chip according to the present embodiment.

Referring to FIGS. 11 to 13, in order to implement a structure robust to an external stress, a plurality of insulation patterns having a polygonal shape may be connected to one another, and thus, shock-resistant patterns SRP1, SRP2, and SRP3 according to another embodiment may be designed in a mesh shape. Here, the polygonal shape may include a triangular shape, a tetragonal shape, or a semispherical shape. In addition, the polygonal shape may also include a combination of two or more of the above shapes, or a combination of other polygonal shapes, as long as it can realize a structure robust to an external stress.

The present embodiment may realize the following effects.

According to the present embodiment, dummy bumps electrically insulated from each other may be further provided in a bump array of a COG type driver chip, and in this case, because the dummy bumps are disposed in a center portion of the bump array where input bumps and output bumps are not provided, the degree of warpage of a driver chip caused by an external stress may be effectively reduced in a COG bonding process.

According to the present embodiment, metal lines of a line layer included in the COG type driver chip may be disposed in an entire region of the bump array, namely, under the dummy bumps as well as the input/output bumps, and thus, the degree of warpage of a driver chip caused by an external stress may be effectively reduced in the COG bonding process.

According to the present embodiment, shock-resistant patterns electrically insulated from each other may be further provided in a region between the metal lines in the line layer included in the COG type driver chip, thereby implementing a COG type driver chip which is reduced in degree of warpage and is robust to a micro crack.

According to the present embodiment, the shock-resistant patterns may be designed so that a plurality of insulation patterns having a hexagonal shape are connected to each other to form a honeycomb shape, and thus, the degree of warpage and micro cracks may be considerably reduced.

The effects according to the present disclosure are not limited to the above examples, and other various effects may be included in the specification.

While the present disclosure has been particularly shown and described with reference to exemplary embodiments thereof, it will be understood by those of ordinary skill in the art that various changes in form and details may be made therein without departing from the spirit and scope of the present disclosure as defined by the following claims.

What is claimed is:

1. A chip on glass (COG) type driver chip comprising:
a base substrate;
at least one insulation layer and at least one line layer alternately stacked on the base substrate; and
a bump array disposed on an uppermost layer of the base substrate,
wherein the bump array comprises:
a plurality of input bumps passing through the at least one insulation layer and connected to metal lines of the at least one line layer;
a plurality of output bumps passing through the at least one insulation layer and connected to the metal lines of the at least one line layer; and
a plurality of dummy bumps electrically disconnected from the at least one line layer with the at least one insulation layer therebetween.

2. The COG type driver chip of claim 1, wherein the bump array comprises a first region, a second region facing the first region, and a third region disposed between the first and second regions,
the plurality of input bumps are disposed in the first region,
the plurality of output bumps are disposed in the second region, and
the plurality of dummy bumps are disposed in the third region.

3. The COG type driver chip of claim 2, wherein the plurality of dummy bumps are arranged in a plurality of rows in the third region.

4. The COG type driver chip of claim 1, wherein the metal lines of the at least one line layer are disposed under the bump array and are disposed to correspond to an entire region of the bump array.

5. The COG type driver chip of claim 1, wherein the at least one line layer further comprises shock-resistant patterns disposed between adjacent metal lines of the at least one line layer.

6. The COG type driver chip of claim 5, wherein the shock-resistant patterns are electrically insulated from the metal lines of the at least one line layer.

7. The COG type driver chip of claim 5, wherein the shock-resistant patterns are electrically insulated from the plurality of input bumps, the plurality of output bumps, and the plurality of dummy bumps.

8. The COG type driver chip of claim 5, wherein the shock-resistant patterns have a honeycomb shape where a plurality of insulation patterns having a hexagonal shape are connected to one another.

9. The COG type driver chip of claim 5, wherein the shock-resistant patterns have a mesh shape where a plurality of insulation patterns having a polygonal shape are connected to one another.

10. The COG type driver chip of claim 1, wherein each of the plurality of input bumps has an individual plane size which is greater than each of the plurality of output bumps and/or each of the plurality of dummy bumps.

11. The COG type driver chip of claim 2, wherein among the first, second, and third regions, a size of the second region is largest, a size of the third region is second largest, and a size of the first region is smallest.

12. A display apparatus comprising:
a display panel including a display area where pixels are provided and a bezel region outside the display area; and
the COG type driver chip of claim 1 mounted directly on a substrate of the display panel and disposed in the bezel region.

13. The display apparatus of claim 12, wherein the COG type driver chip is included in at least one of a source driver configured to drive data lines connected to the pixels and a gate driver configured to drive gate lines connected to the pixels.

14. The display apparatus of claim 13, wherein when the COG type driver chip is included in the source driver, data input pads extending from the data lines of the display panel are electrically connected to the plurality of output bumps included in the COG type driver chip and are not electrically connected to the plurality of dummy bumps included in the COG type driver chip.

15. The display apparatus of claim 13, wherein when the COG type driver chip is included in the source driver, gate input pads extending from the gate lines of the display panel are electrically connected to the plurality of output bumps included in the COG type driver chip and are not electrically connected to the plurality of dummy bumps included in the COG type driver chip.

16. The display apparatus of claim 14, wherein the plurality of output bumps included in the COG type driver chip are electrically connected to corresponding input pads of the display panel through an anisotropic conductive film.
